(19) United States
(12) Patent Application Publication
(10) Pub. No.: US 2009/0079800 A1
(43) Pub. Date: Mar. 26, 2009

(54) ACTUATOR AND LIQUID-EJECTING HEAD

(75) Inventors: Xin-shan LI, Shiojiri-shi (JP); Shiro YAZAKI, Chino-shi (JP)

Correspondence Address: Workman Nydegger;1000 Eagle Gate Tower, 60 East South Temple, Salt Lake City, UT, 84111, US

(73) Assignee: Seiko Epson Corporation, Tokyo (JP)

(21) Appl. No.: 12/234,210

(22) Filed: Sep. 19, 2008

(30) Foreign Application Priority Data
Sep. 21, 2007 (JP) 2007-245314

(51) Int. Cl. B41J 2/045; H01L 41/083

(52) U.S. Cl. 347/68; 310/328

(57) ABSTRACT

An actuator includes a piezoelectric element including a first electrode, a piezoelectric layer, and a second electrode and displaceably disposed above a substrate and a film covering side and top surfaces of the piezoelectric element. The rigidity of the film is 1% or less of that of the piezoelectric layer.

### CROSS REFERENCES TO RELATED APPLICATIONS

The present application claims priority from Japanese Patent Application No. 2007-245314 filed on Sep. 21, 2007, which is incorporated in the present specification.

### BACKGROUND

1. Technical Field

The present invention relates to an actuator including a piezoelectric element disposed above a substrate and a film, and also to a liquid-ejecting head including such an actuator as a liquid-ejecting unit.

2. Related Art

An example of a piezoelectric element for use in an actuator includes a piezoelectric layer formed of a material having an electromechanical conversion function, namely, a piezoelectric material, such as a crystalline dielectric material, and lower and upper electrodes between which the piezoelectric layer is held. This actuator, generally called a flexural mode actuator, is mounted on, for example, a liquid-ejecting head. A typical example of the liquid-ejecting head is an ink-jet recording head in which a diaphragm constituting part of pressure-generating chambers communicating with nozzle orifices for ejecting ink droplets is deformed by piezoelectric elements to compress ink in the pressure-generating chambers, thereby ejecting ink droplets from the nozzle orifices. Some actuators that have been proposed for use in ink-jet recording heads include, for example, piezoelectric elements formed by forming a uniform piezoelectric material layer over the entire surface of a diaphragm by a film-formation technique and processing the piezoelectric material layer into a pattern corresponding to pressure-generating chambers by lithography so that the piezoelectric elements are independently formed for the respective pressure-generating chambers, and a film covering the piezoelectric elements (see, for example, JP-A-9-277520 (pages 2 to 4 and FIG. 2), JP-A-2005-144804 (pages 5 to 10 and FIG. 2), and JP-A-2006-123212 (pages 5 to 6 and FIG. 2)).

There is a problem, however, in that if the film has high rigidity, depending on the material and thickness of the film, it obstructs displacement of the piezoelectric elements, thus impairing desired displacement properties.

Another problem arises in that if the rigidity of the film is lowered by reducing its thickness, it cannot reliably protect the piezoelectric elements from ambient conditions such as atmospheric moisture.

The above problems occur in the above patent documents because none of them specifies the rigidity of the film.

These problems occur not only for actuators mounted on liquid-ejecting heads such as ink-jet recording heads, but also for actuators mounted on other devices.

### SUMMARY

An advantage of some aspects of the invention is that it provides an actuator and liquid-ejecting head in which a piezoelectric element can be reliably protected and operates with little decrease in displacement.

An actuator according to an aspect of the invention includes a piezoelectric element including a first electrode, a piezoelectric layer, and a second electrode and disposed on a substrate and a film covering side and top surfaces of the piezoelectric element. The rigidity of the film is 1% or less of that of the piezoelectric layer.

According to the above aspect, the film can prevent the piezoelectric layer from being damaged by, for example, atmospheric moisture without obstructing displacement of the piezoelectric element, thus ensuring desired displacement properties.

It is preferable that the film be formed of an inorganic insulating material and have a thickness of 30 nm or more. In this case, the film, formed of an inorganic insulating material, can reliably protect the piezoelectric layer.

In particular, it is preferable that the inorganic insulating material be at least one material selected from the group consisting of aluminum oxide, zirconium oxide, titanium oxide, silicon oxide, and tantalum oxide. In this case, the film, formed of a predetermined material, can reliably protect the piezoelectric layer.

It is also preferable that the film be formed of an organic insulating material and have a thickness of 100 nm or more. In this case, the film, formed of an organic insulating material, can reliably protect the piezoelectric layer.

In particular, it is preferable that the organic insulating material be at least one material selected from the group consisting of epoxy resin, polyimide resin, silicon-based resin, and fluororesin. In this case, the film, formed of a predetermined material, can reliably protect the piezoelectric layer.

In addition, it is preferable that a liquid-ejecting head include a flow-channel forming substrate having a pressure-generating chamber communicating with a nozzle orifice and the actuator, which causes a pressure change in the pressure-generating chamber.

This liquid-ejecting head has desired liquid ejection properties because the piezoelectric element has desired displacement properties.

A liquid-ejecting apparatus comprising the above liquid-ejecting head.

And it is possible to provide the liquid-ejecting apparatus which is excellent in durability and reliability.

### BRIEF DESCRIPTION OF THE DRAWINGS

The invention will be described with reference to the accompanying drawings, wherein like numbers reference like elements.

FIG. 1 is an exploded perspective view schematically showing the structure of a recording head according to a first embodiment.

FIG. 2A is a plan view of the recording head according to the first embodiment.

FIG. 2B is a sectional view taken along line IIB-IIB of FIG. 2A.

FIG. 3 is a sectional view taken along line III-III of FIG. 2B.

### DESCRIPTION OF EXEMPLARY EMBODIMENTS

Embodiments of the invention will now be described in detail.

### First Embodiment

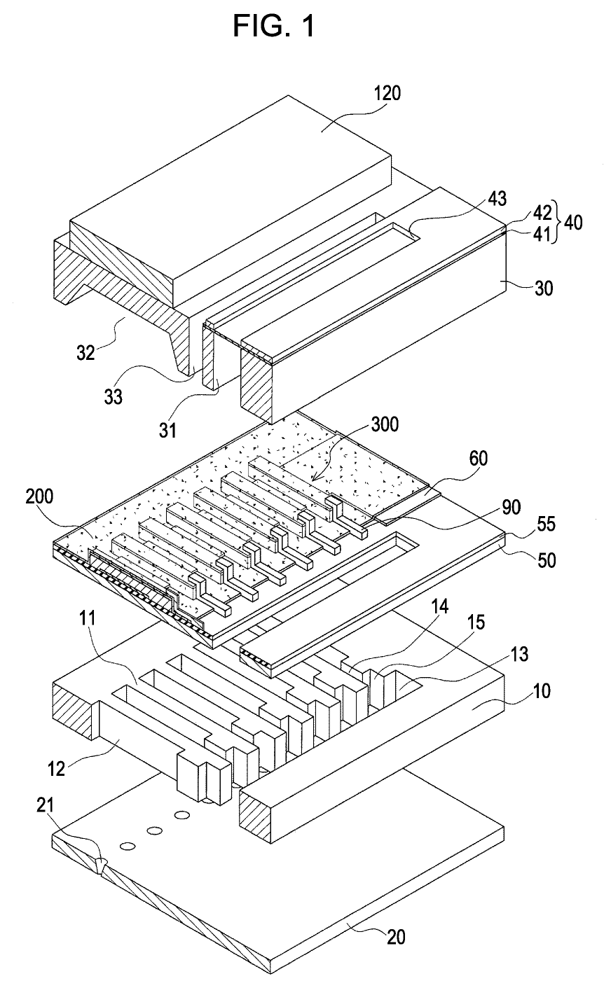

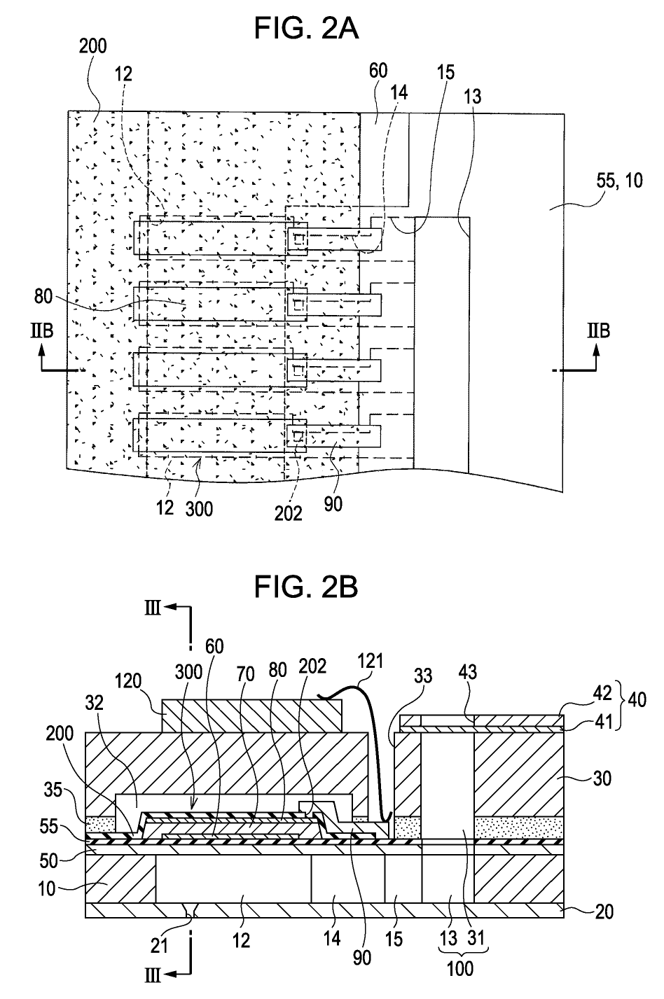

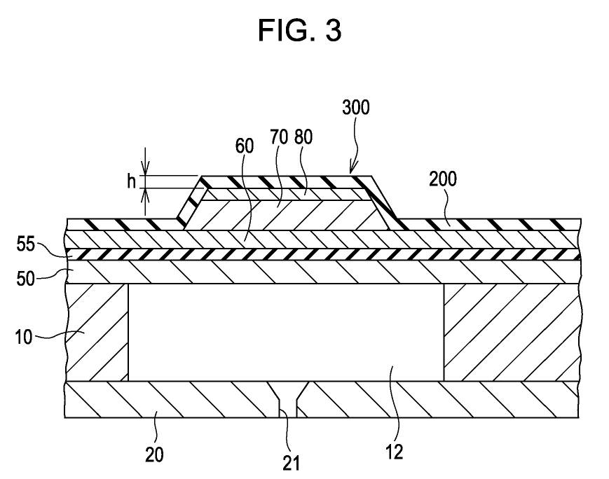

FIG. 1 is an exploded perspective view schematically showing the structure of an ink-jet recording head serving as an example of a liquid-ejecting head according to a first embodiment of the invention. FIG. 2A is a plan view of the ink-jet recording head. FIG. 2B is a sectional view taken along line IIB-IIB of FIG. 2A. FIG. 3 is a sectional view taken along line III-III of FIG. 2B.

Referring to the drawings, a flow-channel forming substrate 10 is a monocrystalline silicon substrate with a (110) crystal plane orientation along its thickness and has an elastic film 50 above one surface thereof. The elastic film 50 is formed of silicon dioxide and has a thickness of 0.5 to 2 μm.

The flow-channel forming substrate 10 has pressure-generating chambers 12 arranged in parallel in the width direction (lateral direction) thereof and partitioned by partitions 11. The pressure-generating chambers 12 are formed by anisotropic etching on the opposite surface of the flow-channel forming substrate 10. The flow-channel forming substrate 10 also has ink supply channels 14 and communication channels 15 partitioned by the partitions 11 at ends of the pressure-generating chambers 12 in the longitudinal direction. The flow-channel forming substrate 10 also has a communication portion 13 at ends of the communication channel 15. The communication portion 13 constitutes part of a reservoir 100 serving as a common ink chamber (liquid chamber) shared by the pressure-generating chambers 12. That is, the flow-channel forming substrate 10 has a liquid flow channel constituted by the pressure-generating chambers 12, the communication portion 13, the ink supply channels 14, and the communication channels 15.

The ink supply channels 14 communicate with the ends of the pressure-generating chambers 12 in the longitudinal direction and have a smaller cross-sectional area than the pressure-generating chambers 12. In this embodiment, for example, the flow channels adjacent to the pressure-generating chambers 12 between the reservoir 100 and the pressure-generating chambers 12 are narrowed in the width direction so that the ink supply channels 14 are narrower than the pressure-generating chambers 12. While the ink supply channels 14 are formed by reducing the width of the flow channels only from one side thereof in this embodiment, they may be formed by reducing the width of the flow channels from both sides thereof. The ink supply channels 14 may also be formed by reducing the thickness of the flow channels, rather than by reducing the width thereof. The communication channels 15 communicate with the ends of the ink supply channels 14 facing away from the pressure-generating chambers 12 and are wider than the ink supply channels 14 (in the lateral direction). In this embodiment, the communication channels 15 have the same cross-sectional area as the pressure-generating chambers 12.

That is, the flow-channel forming substrate 10 has the pressure-generating chambers 12, the ink supply channels 14, which are narrower than the pressure-generating chambers 12 in the lateral direction, and the communication channels 15, which communicate with the ink supply channels 14 and are wider than the ink supply channels 14 in the lateral direction, and they are partitioned by the partitions 11.

A nozzle plate 20 is bonded to the orifice side of the flow-channel forming substrate 10 using, for example, an adhesive or a heat-fusible film. The nozzle plate 20 has nozzle orifices 21 communicating with the pressure-generating chambers 12 near the ends of the pressure-generating chambers 12 facing away from the ink supply channels 14. The nozzle plate 20 has a thickness of, for example, 0.01 to 1 mm and is formed of a material, such as glass ceramic, a monocrystalline silicon substrate, or stainless steel, that has a linear expansion coefficient of, for example, 2.5 to 4.5×10⁻⁶/° C. at 300° C. or less.

The elastic film 50, as described above, is disposed above the side of the flow-channel forming substrate 10 opposite the orifice side thereof. The elastic film 50 is formed of silicon dioxide and has a thickness of, for example, about 1.0 μm. An insulating film 55 is stacked above the elastic film 50. The insulating film 55 is formed of, for example, zirconium oxide (ZrO₂) and has a thickness of, for example, about 0.4 μm. A lower electrode film 60, piezoelectric layers 70, and upper electrode films 80 are formed in layers above the insulating film 55 by the process described below to constitute piezoelectric elements 300. The lower electrode film 60 has a thickness of, for example, about 0.1 to 0.5 μm. The piezoelectric layers 70 are formed of, for example, a lead zirconate titanate (PZT) film, an example of a piezoelectric film, and have a thickness of, for example, about 1.1 μm. The upper electrode films 80 have a thickness of, for example, about 0.05 μm. The piezoelectric elements 300 refer to the portions including the lower electrode film 60, the piezoelectric layers 70, and the upper electrode films 80. In general, one type of electrode is formed as a common electrode while the other type of electrode and the piezoelectric layers 70 are formed for the individual pressure-generating chambers 12 by patterning. The portions which are constituted of one type of electrode and the piezoelectric layers 70 formed by patterning and in which a piezoelectric strain occurs when a voltage is applied between both electrodes are herein referred to as piezoelectric active portions. In this embodiment, the lower electrode film 60 serves as the common electrode of the piezoelectric elements 300, and the upper electrode films 80 serve as the separate electrodes of the piezoelectric elements 300, although they may be reversed for convenience of arranging a drive circuit and wires. In addition, a device in which the piezoelectric elements 300 are disposed above a predetermined substrate (flow-channel forming substrate 10) so that they can be driven is herein referred to as an actuator. While the elastic film 50, the insulating film 55, and the lower electrode film 60 serve as a diaphragm in this embodiment, the elastic film 50 and the insulating film 55 may be eliminated, with only the lower electrode film 60 serving as a diaphragm. Alternatively, the piezoelectric elements 300 themselves may be used substantially as a diaphragm. Either the upper electrode films 80 or the lower electrode film 60 may serve as a first electrode; similarly, either the upper electrode films 80 or the lower electrode film 60 may serve as a second electrode.

The piezoelectric layers 70 of the piezoelectric elements 300 are formed of, for example, a ferroelectric piezoelectric material such as lead zirconate titanate (PZT) or a relaxor ferroelectric prepared by doping it with a metal such as niobium, nickel, magnesium, bismuth, or yttrium.

The piezoelectric elements 300 are covered with a film 200. The film 200 is formed of an insulating material with moisture resistance. In this embodiment, for example, the film 200 is continuously formed over the piezoelectric elements 300 so as to cover side surfaces of the piezoelectric layers 70 and side and top surfaces of the upper electrode films 80. That is, the film 200 is formed over the lower electrode film 60 between the piezoelectric elements 300 disposed in parallel.

The film 200, covering the piezoelectric elements 300, can prevent the piezoelectric elements 300 from being damaged by, for example, atmospheric moisture. The film 200 may be formed of any moisture-resistant material, for example, an inorganic insulating material or an organic insulating material.

An inorganic insulating material that can be used for the film 200 is, for example, at least one material selected from the group consisting of silicon oxide (SiOₓ) zirconium oxide (ZrOₓ), tantalum oxide (TaOₓ), aluminum oxide (AlOₓ), and titanium oxide (TiOₓ). In particular, the inorganic insulating material used for the film 200 is preferably aluminum oxide (AlOₓ), such as alumina (Al₂O₃), as an inorganic amorphous material. With the inorganic insulating material, the film 200 can be formed by, for example, metal-organic deposition (MOD), the sol-gel process, sputtering, or chemical vapor deposition (CVD).

If the film 200 formed of the inorganic insulating material has a thickness of 30 nm or more, it can reliably protect the piezoelectric layers 70 from ambient conditions such as atmospheric moisture.

An organic insulating material that can be used for the film 200 is, for example, at least one material selected from the group consisting of epoxy resin, polyimide resin, silicon-based resin, and fluororesin. With the organic insulating material, the film 200 can be formed by, for example, spin coating or spraying.

If the film 200 formed of the organic insulating material has a thickness of 100 nm or more, it can reliably protect the piezoelectric layers 70 from ambient conditions such as atmospheric moisture.

In addition, the film 200 has such a thickness that its rigidity is 1% or less of that of the piezoelectric layers 70. This prevents the film 200 from obstructing displacement of the piezoelectric elements 300, so that the piezoelectric elements 300 can achieve desired displacement properties, thus providing desired ink (liquid) ejection properties. That is, if the film 200 has such a thickness that its rigidity exceeds 1% of that of the piezoelectric layers 70, the piezoelectric elements 300 cannot achieve desired displacement properties because the film 200 obstructs displacement of the piezoelectric layers 70 (piezoelectric elements 300), thus failing to provide desired ink (liquid) ejection properties.

For example, the rigidity (D) of the film 200 and the piezoelectric layers 70 can be determined from elastic modulus (E), thickness (h), and Poisson's ratio (μ), based on the following equation (1):

$$D = \frac{{Eh}^{3}}{12 ( 1 - {μ}^{2} )} \qquad ( 1 )$$

If the film 200 is formed of the inorganic insulating material, it has an elastic modulus of 100 to 200 GPa and a Poisson's ratio of 0.2 to 0.3. According to the equation (1) above, for example, if the piezoelectric layers 70 formed of PZT has an elastic modulus of 58 GPa, a thickness of 1.1 μm, and a Poisson's ratio of 0.24, the thickness h (see FIG. 3) of the film 200 that is 1% or less of that of the piezoelectric layers 70 is about 150 nm or less.

If the film 200 is formed of the organic insulating material, on the other hand, it has an elastic modulus of 2 to 3 GPa, and accordingly the thickness h of the film 200 that is 1% or less of that of the piezoelectric layers 70 is about 700 nm or less.

Hence, if the film 200 is formed of the inorganic insulating material, it may have a thickness of 30 to 150 nm. If the film 200 is formed of the organic insulating material, it may have a thickness of 100 to 700 nm. In such cases, the film 200 can reliably protect the piezoelectric layers 70 from ambient conditions such as atmospheric moisture without obstructing displacement of the piezoelectric elements 300, thus providing superior ink ejection properties (liquid ejection properties).

Lead electrodes 90 formed of, for example, gold (Au) are disposed above the film 200. Ends of the lead electrodes 90 above one side are connected to the upper electrode films 80 via contact holes 202 in the film 200, whereas ends of the lead electrodes 90 above the other side extend to the ink supply channel 14 of the flow-channel forming substrate 10 and are connected to a drive circuit 120 for driving the piezoelectric elements 300, to be described below, via connection wires 121.

A substrate 30 is bonded to the flow-channel forming substrate 10, on which the piezoelectric elements 300 are disposed, with an adhesive 30 therebetween. The substrate 30 has a reservoir portion 31 in a region opposite the communication portion 13. The reservoir portion 31, as described above, communicates with the communication portion 13 of the flow-channel forming substrate 10, thus constituting the reservoir 100, which serves as a common liquid chamber shared by the pressure-generating chambers 12. Alternatively, with the communication portion 13 divided for the individual pressure-generating chambers 12, only the reservoir portion 31 may be used as the reservoir 100. It is also possible that, for example, the ink supply channels 14 be formed in the members disposed between the flow-channel forming substrate 10 and the substrate 30 (including the elastic film 50 and the insulating film 55) with only the pressure-generating chambers 12 formed in the flow-channel forming substrate 10, so that the reservoir 100 communicates with the pressure-generating chambers 12.

The substrate 30 also has a piezoelectric-element accommodating portion 32 in a region opposite the piezoelectric elements 300. The piezoelectric-element accommodating portion 32 forms a space large enough not to obstruct displacement of the piezoelectric elements 300. This space may be either sealed or unsealed as long as it is large enough not to obstruct displacement of the piezoelectric elements 300.

The substrate 30 also has a through-hole 33 extending therethrough in the thickness direction in a region between the piezoelectric-element accommodating portion 32 and the reservoir portion 31. Part of the lower electrode film 60 and the leading ends of the lead electrodes 90 are exposed in the through-hole 33.

The drive circuit 120 for driving the piezoelectric elements 300 is mounted above the substrate 30. The drive circuit 120 used may be, for example, a circuit board or a semiconductor integrated circuit (IC). The drive circuit 120 is electrically connected to the lead electrodes 90 via the connection wires 121, which are formed of conductive wires such as bonding wires.

The substrate 30 is preferably formed of a material, such as glass or ceramic, having substantially the same thermal expansion coefficient as the flow-channel forming substrate 10. In this embodiment, the substrate 30 is formed of the same material as the flow-channel forming substrate 10, namely, a monocrystalline silicon substrate with a (110) plane orientation.

A compliant substrate 40 including a sealing film 41 and a holding plate 42 is bonded to the substrate 30. The sealing film 41, which seals one side of the reservoir portion 31, is formed of a flexible material with low rigidity (for example, a polyphenylene sulfide (PPS) film with a thickness of 6 μm). The holding plate 42 is formed of a hard material such as a metal (for example, a stainless steel (SUS) sheet with a thickness of 30 μm). Because the holding plate 42 has an opening 43, where the plate 42 is completely removed in the thickness direction, in a region opposite the reservoir 100, the side of the reservoir 100 is sealed with the flexible sealing film 41 alone.

In the ink-jet recording head, thus configured, according to this embodiment, the interior from the reservoir 100 to the nozzle orifices 21 is filled with ink supplied from an external ink-supplying unit (not shown). In response to recording signals from the drive circuit 120, a voltage is applied between the lower electrode film 60 and the upper electrode films 80 corresponding to the pressure-generating chambers 12. This causes flexural deformation of the elastic film 50, the insulating film 55, the lower electrode film 60, and the piezoelectric layers 70 to increase the internal pressure of the pressure-generating chambers 12, thereby ejecting ink droplets from the nozzle orifices 21.

### Other Embodiments

While one embodiment of the invention has been described above, the invention is not limited to the above embodiment. For example, while a monocrystalline silicon substrate is shown as an example of the flow-channel forming substrate 10 in the first embodiment, the invention is not limited to this substrate and is also effective for other substrates such as a silicon-on-insulator (SOI) substrate, a glass substrate, and a MgO substrate.

While an ink-jet recording head has been described as an example of a liquid-ejecting head in the first embodiment, the invention is directed to a wide variety of liquid-ejecting heads and may therefore be applied to liquid-ejecting heads for ejecting liquids other than ink. Other types of liquid-ejecting heads include, for example, various recording heads for use in image-recording apparatuses such as printers, colorant-ejecting heads for use in manufacture of color filters for liquid crystal displays, electrode-material ejecting heads for use in formation of electrodes of organic electroluminescent (EL) displays and field-displays (FEDs), and biological-organic-material ejecting heads for use in manufacture of biochips.

In addition, the invention is not limited to actuators to be mounted on liquid-ejecting heads such as ink-jet recording heads and may also be applied to actuators to be mounted on other devices.

What is claimed is:

1. An actuator comprising:
a piezoelectric element including a first electrode, a piezoelectric layer, and a second electrode, the piezoelectric element being disposed above a substrate; and
a film covering side and top surfaces of the piezoelectric element, wherein the rigidity of the film is 1% or less of that of the piezoelectric layer.

2. The actuator according to claim 1, wherein the film is formed of an inorganic insulating material and has a thickness of 30 nm or more.

3. The actuator according to claim 2, wherein the inorganic insulating material is at least one material selected from the group consisting of aluminum oxide, zirconium oxide, titanium oxide, silicon oxide, and tantalum oxide.

4. The actuator according to claim 1, wherein the film is formed of an organic insulating material and has a thickness of 100 nm or more.

5. The actuator according to claim 4, wherein the organic insulating material is at least one material selected from the group consisting of epoxy resin, polyimide resin, silicon-based resin, and fluororesin.

6. A liquid-ejecting head comprising:
a flow-channel forming substrate having a pressure-generating chamber communicating with a nozzle orifice; and
the actuator according to claim 1, wherein the actuator causes a pressure change in the pressure-generating chamber.

7. A liquid-ejecting apparatus comprising the liquid-ejecting head of claim 1.
